(19) United States
(12) Patent Application Publication
(10) Pub. No.: US 2019/0333677 A1
(43) Pub. Date: Oct. 31, 2019

(54) INDUCTOR APPLIED TO POWER MODULE AND POWER MODULE

(71) Applicant: Delta Electronics (Shanghai) Co., Ltd., Shanghai (CN)

(72) Inventors: Jiayong PAN, Shanghai (CN); Yahong XIONG, Shanghai (CN)

(21) Appl. No.: 16/276,645

(22) Filed: Feb. 15, 2019

(30) Foreign Application Priority Data
Apr. 28, 2018 (CN) 201810401149.9

(51) Int. Cl. H01F 27/24; H01F 27/30; H05K 1/16

(52) U.S. Cl. CPC H01F 27/24; H05K 1/165; H01F 27/30

(57) ABSTRACT

The present application provides an inductor applied to a power module and a power module with the inductor. The inductor comprises a magnetic core, having a through hole, wherein a pin passes through the through hole of the magnetic core, and acts as a winding to form the inductor together with the magnetic core, and the pin is input pins or output pins of the power module. The inductor applied to the power module and the power module provided by present application reduce the area occupied by the inductor on the circuit board of the power module, reduce the conduction power loss of the inductor, eliminate the wire loss between the pin and the inductor, and heat is dissipated through the pin and the magnetic core, which further improves the efficiency of the heat dissipation of the inductor.

### CROSS-REFERENCE TO RELATED APPLICATIONS

This application claims priority to Chinese Patent Application No. 201810401149.9, filed on Apr. 28, 2018, which is hereby incorporated by reference in its entirety.

### TECHNICAL FIELD

The present application relates to an inductor, and more particularly, to an inductor applied to a power module and a power module with the inductor.

### BACKGROUND

Recently, with the development of power technologies, power modules are developing toward high power density and high efficiency. The magnetic components in a power module occupy about 30%-40% of the space of the circuit board, which greatly affects the power density of the power module.

Wherein, these magnetic components include inductor components that filter the input and/or output currents of the power module. In the prior art, all the components including the filter inductor in the power module are mounted on a circuit board by welding, and all the components are connected to each other via circuits in the circuit board. And the entire power module is connected to external devices via input pins and output pins on the circuit board. Therefore, the input and output filter inductors are usually disposed on the circuit board near the corresponding input pins and the corresponding output pins by welding. However, the filter inductor occupies a large area on the circuit board of the power module, and the utilization of the circuit board cannot be improved effectively. Moreover, the power loss of the filter inductor is high, and the heat dissipation of the filter inductor only relies on the portion where the filter inductor and the circuit board are contacted with each other by welding, which results in serious heating problem.

### SUMMARY

The present application provides an inductor applied to a power module and a power module with the inductor, which reduces the occupied area of the inductor on a circuit board of the power module and power loss of the inductor, and optimizes the heat dissipation.

A first aspect of the present application provides an inductor applied to a power module, wherein the inductor includes:

a magnetic core, having a through hole, wherein a pin passes through the through hole of the magnetic core, and acts as a winding to form the inductor together with the magnetic core, and the pin is input pin or output pin.

A second aspect of the present application provides a power module, the power module includes at least one inductor and a circuit board, and the inductor is fixed on the circuit board; the inductor comprises a magnetic core, having a through hole, and a pin passes through the through hole of the magnetic core, and acts as a winding to form the inductor together with the magnetic core; and the pin is input pin or output pin of the power module.

### BRIEF DESCRIPTION OF DRAWINGS

In order to describe technical solutions in embodiments of the present application or in the prior art more clearly, the drawings needed for describing the embodiments or the prior art will be briefly described hereunder. Obviously, the drawings in the following description are only some embodiments of the present application. For those skilled in the art, other drawings also may be obtained based on these drawings without any creative effort.

FIG. 1 is a schematic diagram of a circuit structure of a power module in the prior art;

FIG. 2 is a schematic diagram of a hardware structure of a power module in the prior art;

FIG. 3 is a schematic structural diagram of the first embodiment of an inductor applied to a power module of the present application;

FIG. 4 is a schematic diagram of a hardware structure of the first embodiment of a power module of the present application;

FIG. 5 is a schematic diagram of a cross-section structure of the first embodiment of an inductor applied to a power module of the present application;

FIG. 6 is a schematic structural diagram of the second embodiment of an inductor applied to a power module of the present application;

FIG. 7 is a schematic diagram of a hardware structure of the second embodiment of a power module of the present application;

FIG. 8 is a schematic diagram of a cross-section structure of the second embodiment of an inductor applied to a power module of the present application;

FIG. 9A is a schematic diagram of a hardware structure of the third embodiment of a power module of the present application;

FIG. 9B is a schematic diagram of a hardware structure of the fourth embodiment of a power module of the present application;

FIG. 9C is a schematic diagram of a hardware structure of the fifth embodiment of a power module of the present application;

FIG. 9D is a schematic diagram of a circuit structure of the fifth embodiment of a power module of the present application;

FIG. 10A is a schematic diagram of a hardware structure of the sixth embodiment of a power module of the present application;

FIG. 10B is a schematic diagram of a hardware structure of the seventh embodiment of a power module of the present application;

FIG. 10C is a schematic diagram of a hardware structure of the eighth embodiment of a power module of the present application;

FIG. 11A is a schematic structure diagram of the ninth embodiment of an inductor applied to a power module of the present application;

FIG. 11B is a schematic structure diagram of the tenth embodiment of an inductor applied to a power module of the present application;

FIG. 11C is a schematic structure diagram of the eleventh embodiment of an inductor applied to a power module of the present application;

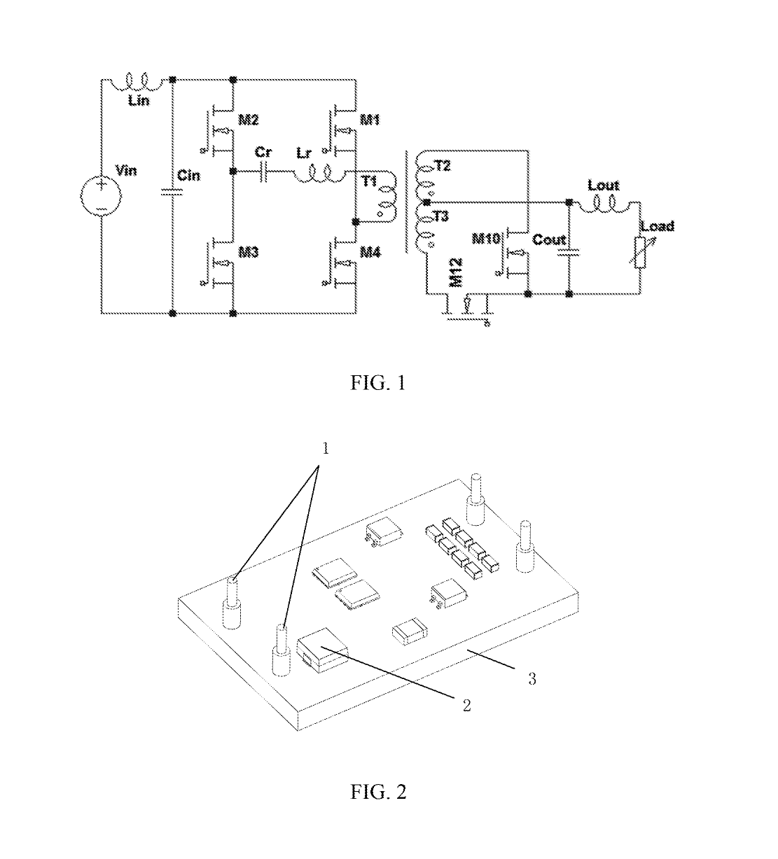

FIG. 1I D is a schematic structure diagram of the twelfth embodiment of an inductor applied to a power module of the present application;

FIG. 12 is a schematic diagram of a connection structure between a power module of the present application and an external circuit board; and

FIG. 13 is a schematic structure diagram of the thirteenth embodiment of an inductor applied to a power module of the present application.

### DESCRIPTION OF EMBODIMENTS

The following clearly and completely describes the technical solutions in embodiments of the present application combining with the accompanying drawings in the embodiments of the present application. Obviously, the described embodiments are merely some but not all of the embodiments of the present application. All other embodiments obtained by a person of ordinary skill in the art based on the embodiments of the present application without any creative efforts shall fall within the protection scopes of the present application.

The terms “first”, “second”, “third”, “fourth”, etc. (if present) in the description and claims of the present application as well as the above-mentioned figures are used to distinguish between similar objects, and are not necessarily used to describe a particular order or sequence. It is to be understood that such used data may be interchanged where appropriate, so that the embodiments of the present application described herein can be implemented in other ways than those illustrated or described herein. In addition, the terms “include” and “have” and any variants thereof are intended to cover a non-exclusive inclusion, for example, a process, method, system, product, or device that comprises a series of steps or units is not necessarily limited to those steps or units that are clearly listed, but may include other steps or units that are not explicitly listed or are inherent to those processes, methods, products, or devices.

The technical solutions of the present application are described in detail below with specific embodiments. The following specific embodiments may be combined with each other, and the same or similar concepts or processes may not be repeated in some embodiments.

As shown in FIG. 1, an LLC circuit is used in the power module to realize the conversion from input voltage to output voltage. Since the switching frequency of the LLC circuit is high, and the input current and output current of the LLC circuit have a small ripple, a filter inductor Lin with small inductance value is set at the input end of the power module to filter the small ripple of the input current, and a filter inductor Lout with small inductance value is set at the output end of the power module to filter the ripple of the output current.

FIG. 2 shows a schematic diagram of a hardware structure of a power module in the prior art, which is a hardware implementation of the power module in FIG. 1, and input pins are taken as an example. As shown in FIG. 2, the input pins 1 and all other components of the power module are mounted on the circuit board 3 by welding. And a filter inductor 2 near the input pins 1 is disposed on the circuit board by welding. Therefore, in the conventional power module, the filter inductor (filter inductor Lin or filter inductor Lout) shown in FIG. 1 is usually disposed on the circuit board near the input pins or the output pins of the power module by welding, just as shown in FIG. 2. Moreover, the heat generated by the power loss of the inductor can only be dissipated through solder junctions that the inductor and the circuit board are contacted by welding, which results in a bad heat dissipation.

In order to solve the problems existing in the prior art, the present application provides an inductor applied to a power module and a power module with the inductor to reduce the area occupied by the inductor on the circuit board of the power module and reduce the power loss generated by the inductor. Specifically, the inductor applied to the power module provided by the present application includes: a magnetic core which has a through hole, a pin of the power module passes through the through hole of the magnetic core. The pin passing through the magnetic core acts as a winding to form an inductor together with the magnetic core. Wherein, the pin is the input pin or the output pin of the power module.

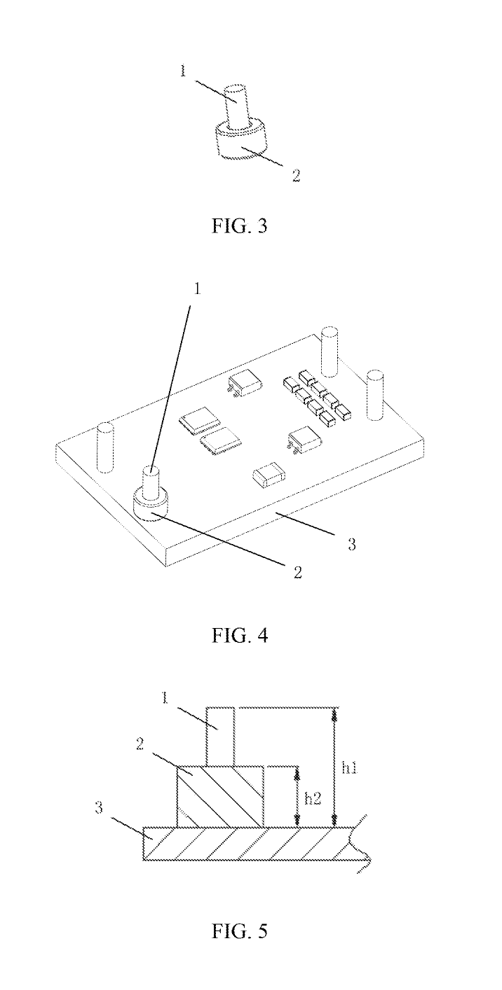

A schematic structural diagram of the first embodiment of an inductor applied to a power module of the present application is shown in FIG. 3. The inductor includes: a magnetic core 2 which has a through hole, and a pin 1 passes through the through hole of the magnetic core 2. Thus, the pin 1 is used as a winding to form an inductor together with the magnetic core 2. The pin 1 shown in FIG. 3 can be an input pin or an output pin of the power module. The input pin and the output pin described herein can be a power pin. The power pin can realize the power transmission from an input end to an output end of the power module, and the current flowing through the power pins changes with a load current or is equal to the load current. Alternatively, the input pin and output pin described herein can also be a pin for transferring a remote switching signal, or an input/output pin for communicating with an external device.

FIG. 4. shows the hardware structure of the power module when the inductor of FIG. 3 is applied to the power module. As shown in FIG. 4, the magnetic core 2 has a through hole, and a pin 1 passes through the through hole of the magnetic core 2. Thus, the pin 1 is used as a winding to form an inductor together with the magnetic core 2, and the inductor is fixed on the circuit board 3 of the power module.

FIG. 5 shows a schematic diagram of a cross-section structure of the first embodiment of an inductor applied to a power module of the present application. As shown in FIG. 5, the height h2 of the magnetic core 2 provided in the present embodiment is smaller than the height h of the pin 1, so that the pin 1 can be used normally to contact with other device. Further, the height h1 of the pin 1 is adjusted according to the different application of the power modules. In some embodiments, the height h2 of the magnetic core 2 does not exceed 20 mm. In addition, the diameter of the pin 1 does not exceed 20 mm.

In summary, in the first embodiment of the present application, the input pin or the output pin of the power module passes through the through hole of the magnetic core, and the input pin or the output pin of the power module forms an inductor with the magnetic core, so that no additional inductor is needed to be welded on the circuit board, thereby reducing the area occupied by the inductor on the circuit board of the power module. Meanwhile, the conduction loss caused by a separate inductor arranged on the circuit board is eliminated, and the wire loss between the pins and the inductor is also eliminated. The heat can be dissipated by the magnetic core and the pin, which further improves the efficiency of the heat dissipation of the inductor. In addition, compared with the way to make an additional inductor on the power module, the inductor provided by the present embodiment is cheaper and is easier to be made and manufactured.

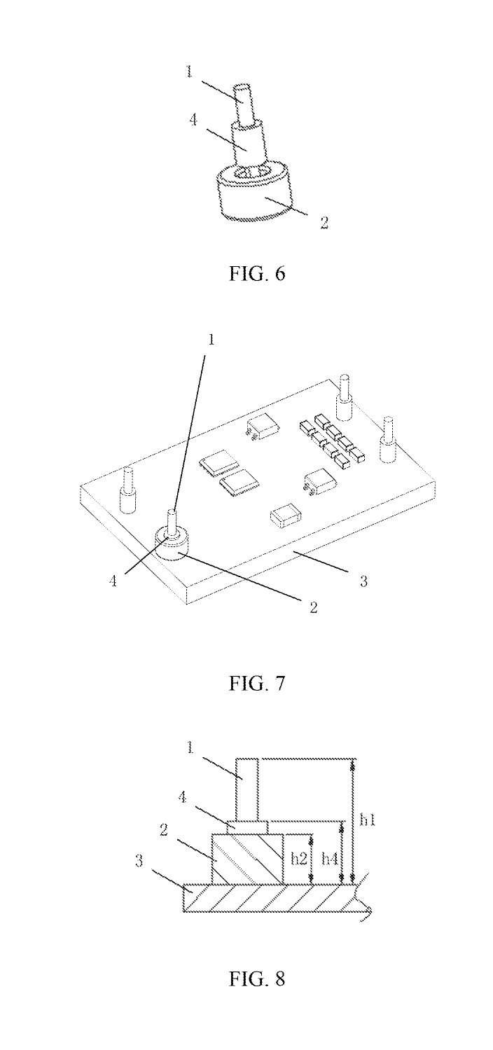

Another schematic structural diagram of the inductor applied to a power module of the present application is disclosed in FIG. 6. As shown in FIG. 6, the pin 1 further includes a spacer 4, and the spacer 4 is set on the pin 1. In some embodiments, the spacer 4 may also be integrally formed with the pin 1. The manner of arranging the spacers and the manner of connecting the spacers with the pins 1 may be well known to those skilled in the art, which will not be repeated again. Wherein, the pin 1 passes through the spacer 4, that is, the spacer is inserted in the through hole of the magnetic core 2. Thus, the pin 1 acts as a winding and forms an inductor together with the magnetic core 2. Similarly, the pin shown in FIG. 6 can be the input pin or output pin of a power module.

As shown in FIG. 7, the magnetic core 2 has a through hole, the magnetic core 2 is sheathed on a spacer 4 that is sheathed on a pin 1 on the circuit board 3 of the power module.

FIG. 8 shows a schematic diagram of a cross-section structure of the inductor of the FIG. 7. As shown in FIG. 8, the height h2 of the magnetic core 2 of the inductor provided in the present embodiment is smaller than the height h1 of the pin 1, so that the pin 1 can be used normally to contact with other device. In addition, the height h1 of the pin 1 is adjusted according to different application of the power modules. Further, the height of the magnetic core 2 does not exceed 20 mm. And the diameter of the pin 1 does not exceed 20 mm. However, the height h4 of the spacer is not limited in the present application, that is, the height h4 of the spacer may be higher than the height h2 of the magnetic core 2 (FIG. 8 is only an example), or may be lower than or equal to the height h2 of the magnetic core 2.

Since a spacer is sheathed on the pin of the power module and the magnetic core is sheathed on the spacer to form an inductor, no additional inductor is needed to be welded on the circuit board, and the area occupied by the inductor on the circuit board of the power module is reduced. Meanwhile, the conduction loss caused by an independent inductor arranged on the circuit board is eliminated, and the wire loss between the pins and the inductor is also eliminated. The heat is dissipated by the magnetic core and the pin, which further improves the efficiency of the heat dissipation of the inductor. In addition, compared with the way of adding an additional inductor to the power module, the inductor provided by the present embodiment is cheaper and is easier to be manufactured.

In some embodiments, the power module in the above embodiments is a DC-DC power module. Further, the power module in the above embodiments is a high-frequency DC-DC power module.

In FIG. 4 and FIG. 7, only one pin passes through one magnetic core on the board to form an inductor of the power module. However, in practical applications, the pin can also pass through the through holes of the plurality of magnetic cores, and then the pin acts as a winding to form an inductor together with the plurality of magnetic cores. Alternatively, a plurality of pins may pass through a single core, wherein the electric potential of the pins sharing one magnetic core are equal. In some embodiments, each input pins corresponds to at least one magnetic core, and passes through the through hole of the corresponding magnetic core to form an inductor; each output pins of the power module corresponds to at least one magnetic core, and passes through the through hole of the corresponding magnetic core to form an inductor together. Further, the input pins of the power module receive a DC voltage, wherein the input pin connected with the positive potential voltage passes through the through hole of at least one magnetic core to form a first inductor, the input pin connected with the negative potential voltage passes through the through hole of at least one magnetic core to form a second inductor, and the first inductor and the second inductor together form a common-mode inductor. And the common-mode inductor can also be set on the output pins.

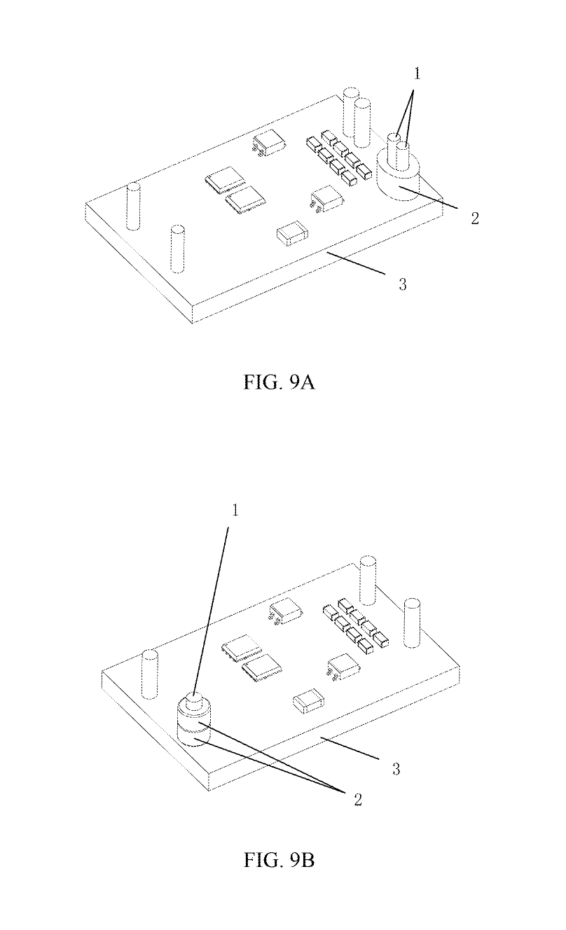

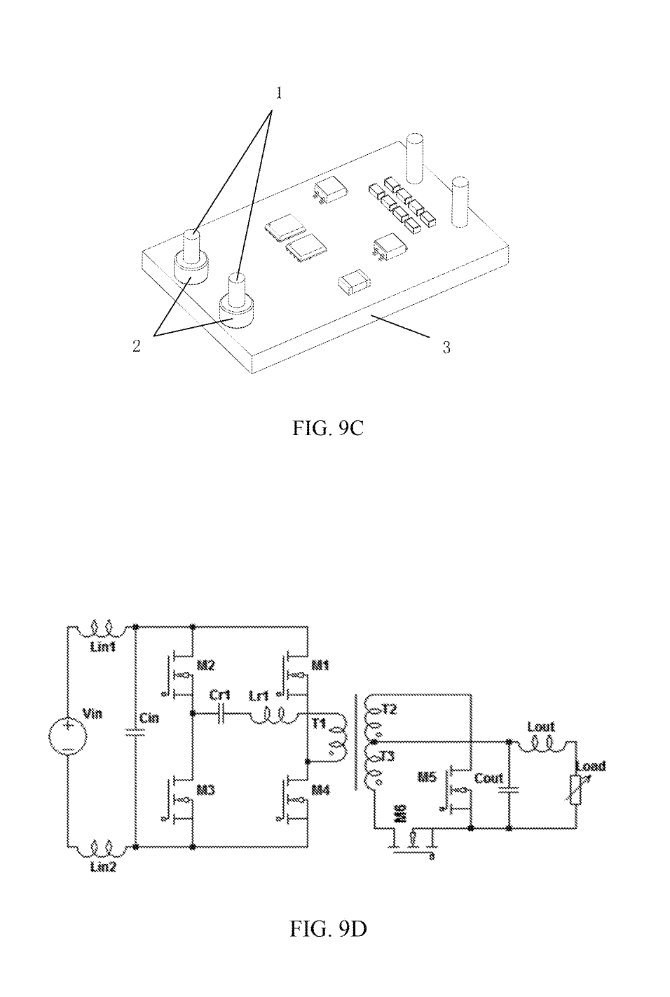

Specifically, FIG. 9A to FIG. 9C illustrate schematic diagrams showing a hardware structure of the inductor applied to a power module which includes different numbers of magnetic cores and different numbers of pins. As shown in FIG. 9A, a plurality of pins 1 pass through the single magnetic core 2 to form an inductor, which requires that each pin has the same electric potential. As shown in FIG. 9B, the pin 1 passes through the through holes of the plurality of magnetic cores 2 and the pin 1 acts as a winding to form an inductor together with the plurality of magnetic cores 2.

As shown in FIG. 9C, a circuit board 3 of the power module has two input pins 1, each of the pins 1 passes through a through hole of the corresponding magnetic core 2 respectively, and acts as a winding to form an inductor together with the corresponding magnetic core 2. Further, if the input pins of FIG. 9C are connected to the DC voltage, the inductor connected to the positive potential and the inductor connected to the negative potential can together form a common-mode inductor. For example, FIG. 9D shows an LLC circuit, and the input and output sides of the LLC circuit are all provided with filter inductors. A first filter inductor Lint is disposed on the positive input line Vin+, and a second filter inductor Lin2 is disposed on the negative input line Vin−, so that the inductor Lin1 of the Vin+ line and the inductor Lin2 of the Vin− line together form a common-mode inductor, to suppress common-mode interference of the circuit. Similarly, an output filter inductor Lout is disposed on output end of the LLC circuit. Further, the output filter inductor can also be common-mode inductor. Wherein, the circuit structure is not limited thereto.

FIG. 9A to FIG. 9C are merely exemplary description and not show the spacers. However, all or some of the inductors in FIG. 9A to FIG. 9C may be the inductor including the spacer, and the implementation manner and the detailed principle are same as those of the spacer in FIG. 6, which will not be repeated again.

Further, in the above embodiments, the shape of the magnetic core and the shape of the through hole may be same or different, for example, the shape of the magnetic core is circular, rectangular, elliptical or polygonal. Further, the shape of the through hole of the magnetic core matches the sectional shape of the pin, and the shape of the through hole of the magnetic core and the sectional shape of the pin may be same or different. For example, the cross-sectional shape of the pin may be circular, rectangular or polygonal, and the shape of the through hole of the magnetic core may be a circular or other shapes which match the cross-sectional shape of the pin. That is, the pin can pass through the through hole of the magnetic core.

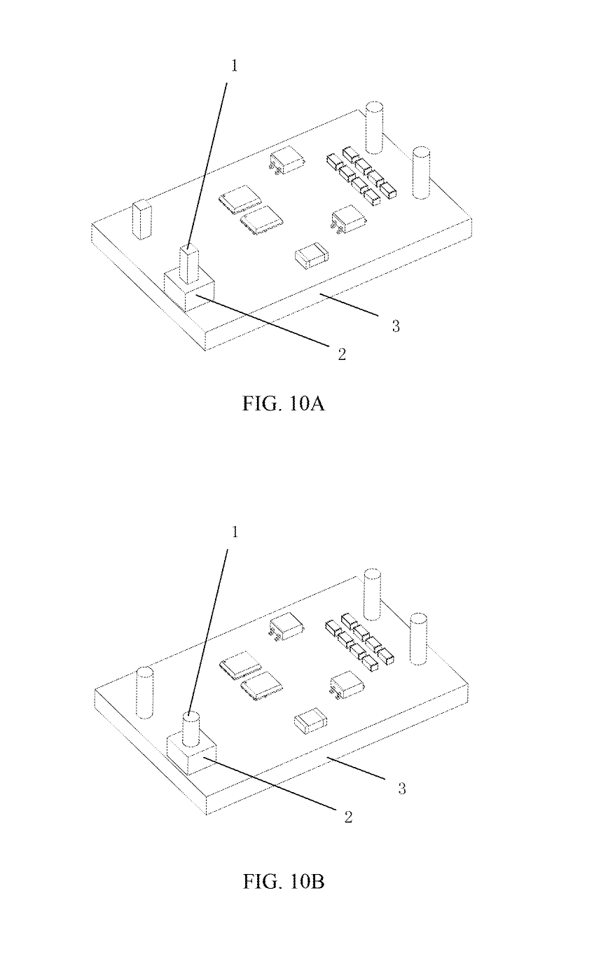

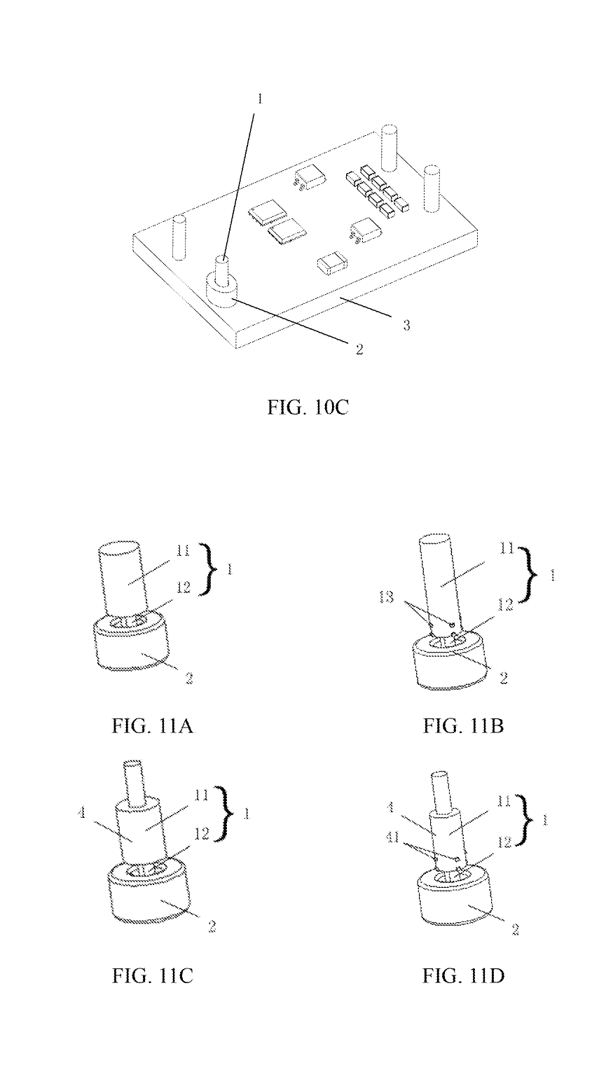

FIG. 10A to FIG. 10C show schematic diagrams of hardware structure of the different embodiment of a power module of the present application. Wherein, the shape of the magnetic core and the shape of the through hole may be the same or different, and the shape of the through hole of the magnetic core and the sectional shape of the pin may be the same or different. As shown in FIG. 10A, the shape of the magnetic core 2 is rectangular, the shape of the through hole of the magnetic core 2 is rectangular, and the cross-sectional shape of the pin 1 is also rectangular, but the present application is not limited thereto. As shown in FIG. 10B, the shape of the magnetic core 2 is rectangular, the shape of the through hole of the magnetic core 2 is circular, and the cross-sectional shape of the pin 1 is also circular, but the present application is not limited thereto. As shown in FIG. 10C, the shape of the magnetic core 2 is elliptical, the shape of the through hole of the magnetic core 2 is circular, and the cross-sectional shape of the pin 1 is also circular, but the present application is not limited thereto. Further, the length of the magnetic core does not exceed 20 mm, for example, the diameter of the circular magnetic core in FIG. 4 does not exceed 20 mm, the side length of the rectangular magnetic core in FIG. 10A does not exceed 20 mm, and the long axis of the elliptical magnetic core in FIG. 10C does not exceed 20 mm.

It should be noted that, the embodiments in FIG. 10A to FIG. 10C are merely exemplary description, and do not show spacer. However, all or some of the embodiments in FIG. 10A to FIG. 10C may be installed with the spacer, and the implementation manner and the detailed principle are same as the spacer in FIG. 6, which will not be repeated again.

Further, the magnetic core 2 can be mounted on the pin 1 in a manner of gluing, tight fitting or other ways.

For example, the magnetic core 2 shown in FIG. 3 is adhered to the pin 1 by glue, and the magnetic core 2 shown in FIG. 6 is adhered to the spacer 4 of the pin by glue.

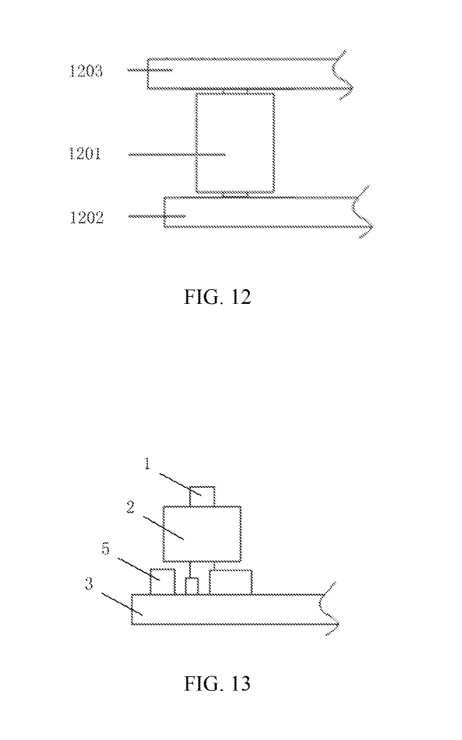

FIG. 11A shows a schematic diagram of the magnetic core 2 installed on the pin 1 by a manner of tight fitting. Wherein the pin 1 includes: a first portion 11 and a second portion 12, and the diameter of the first portion 11 is slightly larger than the diameter of the through hole of the magnetic core 2. When the magnetic core 2 is sheathed on the second portion 12, the magnetic core 2 cannot fall off due to the clamping with the first portion 11. Then the second portion 12 of the pin 1 is mount and fixed on the circuit board 3 of the power module.

FIG. 11C shows a schematic diagram of the magnetic core 2 installed on the pin 1 by a spacer for a tight fit. Wherein the outer diameter of the spacer 4 is slightly larger than the diameter of the through hole of the magnetic core 2. When the magnetic core 2 is sheathed on the second portion 12 of the pin 1, the magnetic core 2 does not fall off due to the clamping with the spacer 4. Then the second portion 12 of the pin 1 is mounted and fixed on the circuit board 3 of the power module.

In addition, FIG. 11B and FIG. 11D illustrate another manner to install the inductors. In FIG. 11B, a plurality of small protrusions 13 are disposed on the first portion 11 of the pin 1 to ensure that the magnetic core 2 will not fall off due to the projections 13. Similarly, FIG. 11D shows the manner in which the protrusions 13 are provided on the spacer of the pin to prevent the magnetic core 2 from falling off.

The present application also provides a power module with the above inductor, the power module includes at least one inductor and a circuit board, and the inductor is fixed on the circuit board. Wherein the inductor comprises a magnetic core, having a through hole, and a pin passes through the through hole of the magnetic core, and acts as a winding to form the inductor together with the magnetic core, and the pin is input pin or output pin of the power module.

FIG. 12 shows a schematic diagram of a connection structure between a power module of the present application and an external circuit board. As shown in FIG. 12, the power module includes one inductor 1201 and a circuit board 1202, and the inductor 1201 is fixed and connected to the circuit board 1202. Further, the power module is electrically connected to the external device or the external circuit board 1203 through an input pin or an output pin. Wherein the number of the inductors 1201 disposed on the circuit board 1202 is not limited thereto. The specific hardware structure diagram of the present embodiment can refer to the examples in FIG. 4, FIG. 7, and FIG. 9A to FIG. 10C.

Therefore, in the power module provided by the present application, the input/output pin of the power module passes through the magnetic core. The inductor is formed by a magnetic core and the pin of the power module, which reduces the area occupied by the inductor on the circuit board of the power module. Meanwhile, the conduction loss caused by an independent inductor arranged on the circuit board is eliminated, and the wire loss between the pins and the inductor is also eliminated. The heat of the inductor is dissipated by the magnetic core and the pin, which improves the efficiency of the heat dissipation of the inductor. In addition, compared with the way to add an additional inductor on the power module, the power module provided by the present embodiment is cheaper and is easier to be manufactured.

Alternatively, in the power module provided in present application, the magnetic core of the inductor 1201 is fixed and connected to the circuit board 1202 by manner of gluing.

Further, a space is provided between the magnetic core of the inductor and the circuit board in the power module. Other components on the board can be mounted within the space. For example, as shown in FIG. 13, the pin 1 is disposed on the circuit board 3, the magnetic core 2 is disposed on the pin 1, and there is a space between the magnetic core 2 and the circuit board 3. Other components 5 of the power module on the circuit board 3 can be disposed on the circuit board 3 within the space. The height of the space can be adjusted according to the height of the disposed components. The utilization efficiency of the circuit board 3 of the power module can be further improved, and the whole area of the circuit board 3 can be reduced.

Alternatively, the topological structure of the power module may be an LLC topology or an LCC topology. In addition, series resonant topology, parallel resonant topology, forward topology, fly-back topology, full bridge topology, half bridge topology, buck topology or boost topology can also be applied in the power module of the present application.

Finally, it should be noted that the above embodiments are only used to explain the technical solutions of the present application, which are not limited thereto; although the present application has been described in detail with reference to the foregoing embodiments, those skilled in the art should understand that the technical solutions described in the foregoing embodiments may be modified or equivalently substituted for some or all of the technical features; whereas these modifications or substitutions do not make the essence of the corresponding technical solutions depart from the scope of the technical solutions of the embodiments of the present application.

What is claimed is:

1. An inductor applied to power module, comprises:
a magnetic core, having a through hole, wherein a pin passes through the through hole of the magnetic core, and acts as a winding to form the inductor together with the magnetic core, and
wherein the pin is an input pin or an output pin of the power module.

2. The inductor according to claim 1, wherein the power module is a DC-DC power module.

3. The inductor according to claim 2, wherein the power module is a high-frequency DC-DC power module.

4. The inductor according to claim 1, wherein the power module comprises a plurality of the magnetic cores, the pin passes through the through holes of the magnetic cores and acts as a winding to form the inductor together with the magnetic cores.

5. The inductor according to claim 1, wherein a plurality of the pins pass through same magnetic core, and the pins sharing the same magnetic core have the same electric potential.

6. The inductor according to claim 1, wherein the input pins receive a DC voltage, the input pin receiving a positive potential voltage passes through the through hole of at least one magnetic core to form a first inductor, the input pin receiving a negative potential voltage passes through the through hole of at least one magnetic core to form a second inductor, and the first inductor and the second inductor together form a common-mode inductor.

7. The inductor according to claim 1, wherein the output pins output a DC voltage, the output pin outputting a positive potential voltage passes through the through hole of the at least one magnetic core to form a third inductor, the output pin outputting a negative potential voltage passes through the through hole of the at least one magnetic core to form a fourth inductor, and the third inductor and the fourth inductor together form a common-mode inductor.

8. The inductor according to claim 1, wherein a height of the magnetic core does not exceed 20 mm.

9. The inductor according to claim 1, wherein a length of the magnetic core does not exceed 20 mm.

10. The inductor according to claim 1, wherein the pin has a spacer and the magnetic core is disposed on the spacer of the pin.

11. The inductor according to claim 1, wherein the magnetic core is mounted on the pin in a manner of gluing.

12. The inductor according to claim 1, wherein the magnetic core is mounted on the pin in a manner of tight-fitting.

13. The inductor according to claim 1, wherein a shape of the through hole of the magnetic core matches a sectional shape of the pin.

14. The inductor according to claim 13, wherein the sectional shape of the pin is a round, rectangular or polygon.

15. The inductor according to claim 1, wherein a shape of the magnetic core is a round, rectangular, elliptical or polygon.

16. A power module, comprising at least one inductor and a circuit board, and the inductor is fixed on the circuit board;
wherein the inductor comprises a magnetic core having a through hole, and a pin passing through the through hole of the magnetic core, and acting as a winding to form the inductor together with the magnetic core; and
wherein the pin is input pin or output pin of the power module.

17. The power module according to claim 16, wherein the magnetic core of the inductor is fixed to the circuit board in a manner of gluing, and the pin is welded on the circuit board.

18. The power module according to claim 16, wherein a space is provided between the magnetic core of the inductor and the circuit board.

19. The power module according to claim 18, wherein the circuit board is provided with electronic components within the space.

20. The power module according to claim 16, wherein a topological structure of the power module is an LLC or an LCC.
